(19) United States
(12) Patent Application Publication
(10) Pub. No.: US 2026/0202443 A1
(43) Pub. Date: Jul. 16, 2026

(54) PROBE HEAD WITH IMPROVED COOLING SYSTEM

(71) Applicant: TECHNOPROBE S.P.A., Cernusco Lombardone (LC) (IT)

(72) Inventor: Raffaele VALLAURI, Cernusco Lombardone (LC) (IT)

(73) Assignee: TECHNOPROBE S.P.A., Cernusco Lombardone (LC) (IT)

(21) Appl. No.: 19/136,609

(22) PCT Filed: Dec. 18, 2023
(86) PCT No.: PCT/EP2023/086329

§ 371 Date: Jun. 6, 2025

(30) Foreign Application Priority Data
Dec. 21, 2022 (IT) 102022000026193

(51) Int. Cl. G01R 1/44; G01R 1/073

(52) U.S. Cl. CPC G01R 1/44; G01R 1/07307

(57) ABSTRACT

A probe head for testing a device under test integrated on a semiconductor wafer contains a plurality of contact probes having a body with first and second end portions adapted to contact respective pads, a guide with guide holes for housing the contact probes, and an air-conveying system to convey an air flow into the probe head to facilitate heat dissipation. The probe head further includes a conductive portion on the guide having a group of the guide holes which contacts and short circuits a corresponding group of contact probes in the group of holes and intended to carry a determined type of signal, defining a conductive domain on the guide. The heat dissipation conductive portion formed on the guide extends the conductive domain so that the air flow of the air-conveying system facilitates the dissipation of the heat exchanged by the heat dissipation conductive portion.

### FIELD OF APPLICATION

The present invention relates to a probe head adapted to perform the test of electronic device integrated on a semiconductor wafer. The following description is made with reference to this field of application with the sole aim of simplifying the exposition thereof.

### PRIOR ART

As it is well known, a probe head is essentially a device adapted to electrically connect a plurality of pads of a microstructure, in particular an electronic device integrated on a semiconductor wafer, with corresponding channels of a testing apparatus that performs the functionality testing thereof.

The test, which is performed on integrated circuits, is particularly useful for detecting and isolating defective devices as early as in the production phase. Usually, probe heads are therefore used for the test of circuits integrated on a wafer before cutting and assembling them inside a chip containment package.

A probe head essentially comprises a plurality of movable contact probes held by at least one pair of supports or guides which are substantially plate-shaped and parallel to each other. Said plate-shaped supports are equipped with suitable guide holes and are arranged at a certain distance from each other in order to leave a free space or air gap for the movement and possible deformation of the contact probes, which are typically formed by wires of special alloys with good electric and mechanical properties.

The contact probes generally extend between a first end portion, intended to contact the pads of the device under test, and a second end portion, intended to contact a space transformer or a printed circuit board (PCB).

The proper operation of a probe head is basically linked to two parameters: the vertical movement (overtravel) of the contact probes and the horizontal movement (scrub) of the contact tips of said probes onto the pads during the contact with the device under test. All these features should be evaluated and calibrated in the manufacturing step of a probe head, and the proper electrical connection between contact probes and device under test should always be ensured.

Furthermore, in an ever-increasing number of applications, for instance in high frequency applications, at last one of the guides has a conductive portion (in particular a metallization) aimed at electrically connecting (namely short circuiting) specific groups of contact probes to each other, forming a common conductive plane for said groups of probes. In this way it is possible to improve the frequency performance of the probe head and to carry increasingly higher frequency signals with low noise, as well as to avoid probe burning phenomena.

In the probe heads of the above type, in case of tests at high temperatures, the thermal expansions of the components thereof can undermine their correct behaviour, due to the different thermal expansion coefficients of the different materials which said elements are made up of. It is indeed common to fasten the elements that make up a probe head through screws, which, in particular during a temperature testing, apply to the several plates a bond which tends to cause them to buckle, resulting in a malfunction of the probe head as a whole. This problem is particularly felt in case of big-sized probe heads, such as for instance the probe heads for the test of memory devices such as the DRAMs, or in general the probe heads for the multi-dice test. For this kind of probe heads, indeed, failure to control the thermal expansion of the components leads to considerable problems in the testing phase.

Moreover, during the test operations, a large quantity of heat is generated by the components of the probe head itself; for instance, the contact probes may heat up due to the passage of the several signals, thus increasing the heat present inside the probe head, in particular in case of a probe head equipped with a very high number of contact probes. Analogously, the abutment of said contact probes onto the pads of the space transformer and the friction with the walls of the guide holes produces unwanted heat that accumulates, therefore there is the need of limiting the heating of the probe head.

The technical problem of the present invention is to provide a probe head having such structural and functional features as to allow overcoming the limitations and drawbacks still affecting the known solutions, in particular a probe head that is able to effectively dissipate the heat during the operation thereof.

### SUMMARY OF THE INVENTION

The solution idea underlying the present invention is to use an extension of a conductive domain formed on a guide as heat dissipation element able to dissipate the heat even of the innermost probes, which are relatively little affected by the presence of a cooling air flow. In particular, there is provided a system configured to convey air into the probe head, in particular into a housing thereof, and a conductive portion is formed on the guide in order to dissipate heat, said portion being electrically connected with the above conductive domain and being used to carry heat into a determined area of the guide, so as to be directly hit by the air flow and to facilitate the dissipation of the exchanged heat.

Based on this solution idea, the above technical problem is solved by a probe head for the testing of a device under test, comprising a plurality of contact probes comprising a body extending along a longitudinal axis between a first end portion and a second end portion, said end portions being adapted to contact respective pads, at least one guide equipped with guide holes for (slidingly) housing the contact probes, and an air-conveying system configured to convey an air flow (for instance coming from an external source) into the probe head and to thereby facilitate heat dissipation, wherein the probe head comprises a conductive portion formed on the guide, said conductive portion including at least one group of holes of the guide holes and being adapted to contact and short circuit a corresponding group of contact probes that are housed in said group of holes and intended to carry a determined type of signal, thereby defining at least one conductive domain on the guide, and wherein the probe head further comprises a heat dissipation conductive portion formed on the guide and arranged so that the air flow of the air-conveying system passes at the same, said heat dissipation conductive portion being (electrically) connected to the conductive portion so as to extend the conductive domain and so that said air flow of said air-conveying system facilitates the dissipation of the heat exchanged by said heat dissipation conductive portion.

More particularly, the invention comprises the following additional and optional features, taken singularly or in combination if needed.

According to an aspect of the present invention, the probe head may comprise a plurality of conductive portions corresponding to different conductive domains, each of said conductive domains being configured to short circuit probes adapted to carry a different respective signal, and wherein at least one of said domains (for instance an innermost domain) is connected to a respective heat dissipation conductive portion.

According to an aspect of the present invention, the conductive domains may be different power domains, and/or ground domains, and/or domains adapted to carry operational signals, in particular power domains.

According to an aspect of the present invention, at least one conductive domain may be divided into distinct conductive sub-domains separated from each other, and wherein each of said conductive sub-domains is configured to distribute a same determined type of signal between the contact elements short circuited by them separately from the other conductive sub-domains, wherein at least one of said conductive sub-domains (for instance an internal sub-domain surrounded by other outermost domains) is connected with a respective heat dissipation conductive portion.

According to an aspect of the present invention, the guide may be a lower guide.

According to another aspect of the present invention, the guide may be an intermediate guide of the probe head, wherein a lower guide is arranged between said intermediate guide and the device under test.

According to an aspect of the present invention, the probe head may further comprise an upper guide separated from the lower guide and provided with respective guide holes, the lower guide being the closest guide to the device under test.

According to an aspect of the present invention, the contact probes may be included in at least one first area or active area of the guide, said active area being contiguous to a second area of the guide which does not include the contact probes. In particular, the air-conveying system may be configured to convey the air flow at at least one part of the second area of the guide, and the heat dissipation conductive portion may be formed in said second area, thereby extending the conductive domain out of the active area.

According to an aspect of the present invention, the conductive portion and the heat dissipation conductive portion may be arranged on a face of the guide.

According to an aspect of the present invention, the probe head may further comprise a heat dissipation layer in contact with at least part of the face of the guide.

According to an aspect of the present invention, the heat dissipation layer may be made of a high thermal conductivity material selected from diamond, silicon carbide and silver-diamond compound with a diamond percentage between 50 and 99%, preferably diamond.

According to an aspect of the present invention, the probe head may further comprise a housing configured to house the contact probes, wherein the air-conveying system is configured to convey the air flow into the housing.

According to an aspect of the present invention, the housing may be shaped so that at least part of the air-conveying system is formed in said housing, which is suitably shaped to allow conveying the air flow thereinto by input ducts and to cause said air flow to flow out by output ducts.

According to an aspect of the present invention, the ducts of the housing may be configured so that the input air flow is in a direction lying in a plane parallel (for instance tangential flow) to the guide and the output air flow is divided into at least two flow portions, the input air flow being split based on the number of dices (or chips) to be tested by said probe head.

The features and advantages of the probe head according to the invention will become apparent from the following description of an embodiment thereof, given by way of indicative and non-limiting example, with reference to the attached drawings.

### BRIEF DESCRIPTION OF THE DRAWINGS

In these drawings:

FIG. 1 schematically shows a probe head according to embodiments of the present invention;

FIG. 2 schematically shows aspects of a probe head according to further embodiments of the present invention;

FIG. 3 schematically shows a schematic and exemplifying top view of a guide according to an embodiment of the present invention;

FIG. 4 is a deliberately schematic top view of a guide of the probe head according to embodiments of the present invention; and

FIGS. 5A-5C show views of a housing and of an air flow conveyed thereinto according to embodiments of the present invention.

### DETAILED DESCRIPTION

With reference to these figures, reference number 20 globally and schematically indicates a probe head made according to the present invention.

It should be noted that the figures represent schematic views and are not drawn to scale, but instead they are drawn so as to emphasize the important features of the invention. Furthermore, in the figures, the different elements are depicted in a schematic manner, their shape varying depending on the desired application. It is also worth noting that in the figures the same reference numbers refer to elements that are identical in shape or function. Finally, particular features described in relation to an embodiment illustrated in a figure are also applicable to the other embodiments illustrated in the other figures.

Moreover, it is noted that, unless expressly indicated, process steps may also be reversed if needed.

The probe head 20 is adapted to connect (directly or indirectly through a space transformer and/or a PCB) with an apparatus (not illustrated in the figures) to perform the test of electronic devices integrated on a semiconductor wafer 23, for instance (but not necessarily) high frequency devices or big-sized memory devices.

It is noted that, in the context of the present invention, the term “probe head” is used to indicate a test device without this being limited by the presence or not of particular components, in addition to what is defined in the attached claims. In general, said term thus indicates an assembly of components associable with further components for testing electronic devices integrated on the aforementioned semiconductor wafer 23, and thus in general it indicates a measurement system of electronic devices.

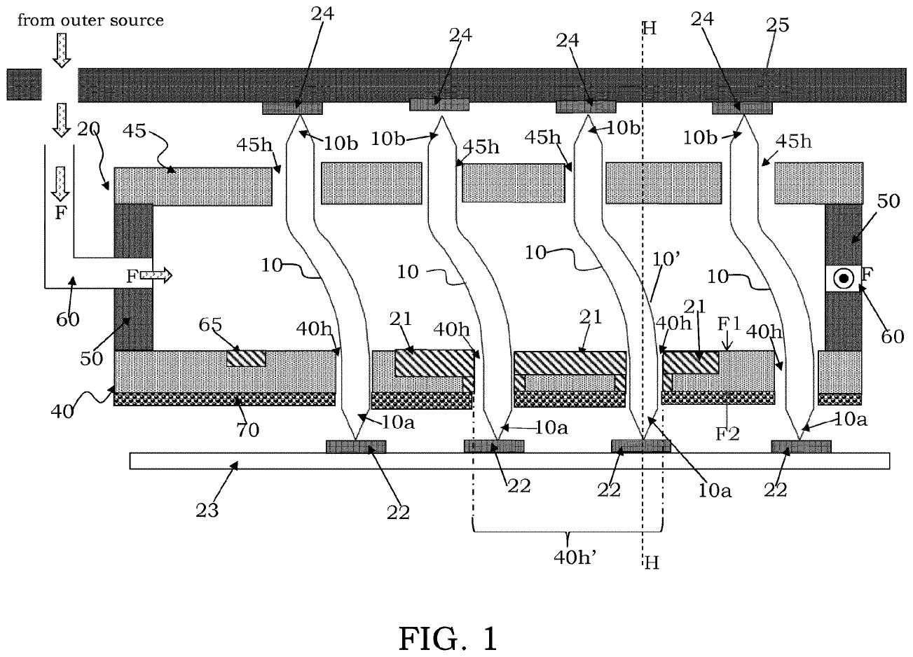

With reference to the sectional view of FIG. 1, the probe head 20 comprises a plurality of contact probes 10 intended to connect the device under test integrated in the semiconductor wafer 23 with the testing apparatus.

In order to house the contact probes 10, the probe head 20 comprises at least one guide 40 equipped with guide holes 40h within which said contact probes 10 are able to slide. The guide 40 thus allows, along with the guide holes 40h thereof, slidingly housing the contact probes 10.

Each contact probe 10 comprises a probe body 10′ extending along a longitudinal axis H-H between a first end portion 10a and a second end portion 10b, which are adapted to contact respective contact pads. By way of example, the first end portion 10a (also called contact tip) is adapted to contact pads 22 of the device under test integrated on the semiconductor wafer 23, whereas the second and opposite end portion 10b (also called contact head) is adapted to contact pads 24 of a space transformer or of a printed circuit board (PCB) associable with the probe head 20, said component being generically identified with reference number 25. Clearly, though the end portions 10a and 10b in the enclosed figures end with a pointed shape, they are not limited thereto and may have any shape suitable for the needs and/or circumstances.

During the bending of the contact probes 10 (in particular during the vertical movement of the probes, indicated in the field as “overtravel”), a sliding contact occurs between probe body 10′ and wall of the guide hole. The probe body 10′ thus comprises a portion intended to be at least partially inserted into a guide hole 40h of the guide 40 of the probe head 20 and, during the movement of the contact probe 10, it performs a contact with said guide hole 40h, in particular a sliding contact.

The guide 40 is preferably a lower guide of the probe head 20 and thus, as known in the field, it is close to the first end portion 10a intended to contact the device under test, namely it is closer to the device under test during the test compared to an upper guide or to an intermediate guide. In the rest of the present description, the guide 40 will thus be also identified as lower guide of the probe head 20.

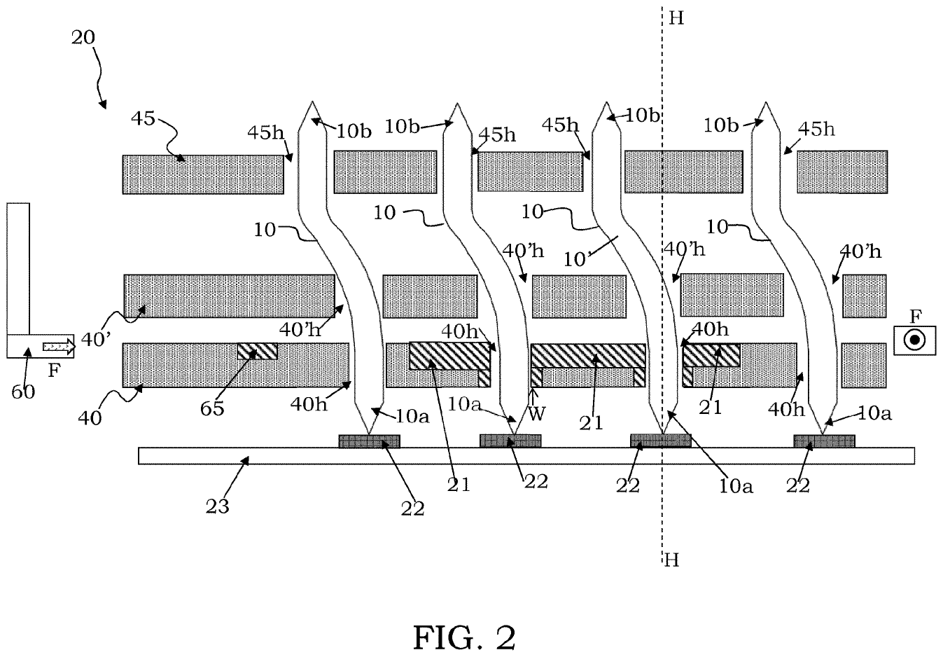

In an embodiment, the probe head 20 may also comprise an intermediate guide 40′ equipped with respective guide holes 40′h (as illustrated in FIG. 2, where for the sake of simplicity some components of the probe head are not illustrated), wherein the lower guide 40 is arranged, in use, between said intermediate guide 40′ and the device under test.

Still with reference to FIG. 1, in an embodiment, the probe head 20 may further comprise an upper guide 45 separated from the lower guide 40 and equipped with respective guide holes 45h. Should there also be the intermediate guide 40′, said intermediate guide is arranged between the lower guide 40 and the upper guide 45, wherein the lower guide 40 is still the closest guide to the device under test.

According to embodiments of the present invention, the probe head 20 further comprises a housing or containment element 50 configured to house the contact probes 10 and to also provide a support and connection structure between the guides.

In the embodiment of FIG. 1, the housing 50 is interposed between the lower guide 40 and the upper guide 45 and is suitably shaped so as to house the contact probes 10 therein.

Suitably, the probe head 20 also comprises an air-conveying system 60 configured to convey an air flow (generated externally—for instance by an external source—and indicated in the figures by the arrow F) thereinto, in particular into the housing 50, thereby facilitating the dissipation of the generated heat. Details of the air-conveying system 60 will be illustrated hereinafter.

Furthermore, it is known in the field that the fixed position of the power and ground signals (due to the layout of the pads of the device under test) and the shape of the probes limit the control of the signal impedance inside the probe head and also the control of the noise caused on the signal probes by other nearby signals, which limits the frequency performance of the probe head.

For this reason, in particular in high-frequency applications (still more particularly in RF applications), the ground probes (and the supply and power ones as well) are short circuited through a metallization on the guide, by short circuiting probes of a same domain and making the ground contact inside the probe head available in order to connect possible shields. Moreover, in the case of devices with different ground/supply domains on the device, then joined on the PCB, the metallization allows reducing the loop inductance between a supply and the related ground.

These metallizations are very useful even in the case of supply domains, as they for instance contribute to the reduction of the probe burning phenomenon.

By way of example, let us consider the case in which a certain supply for a device under test is contacted by a single probe of the head, which is short circuited with other probes that carry supplies sharing the same power supply. Well, when the current of this supply encounters the metallization that short-circuits all of the probes of this domain, it splits among all of the short-circuited probes, thereby allowing the reduction of inductance and equivalent resistance compared to the case in which this current remains confined in a single probe up to the PCB.

It is thus clear that the presence of metallizations on the guide, which short circuit groups of probes and create a common conductive plane (which short circuit a certain domain forming a conductive domain), allows both reducing the noise and increasing the performance of the probe head 20.

To this end, according to the present invention, the guide 40 comprises at least one conductive portion 21 (also indicated as conductive plate) which includes and electrically connects the holes of at least one group (indicated with reference 40h′) of the guide holes 40h and is adapted to contact, and thus to short circuit, a corresponding group of contact probes, which are intended to carry a same type of signal, in particular intended to carry a certain ground or supply or operational signal. In other words, the conductive domains may thus be power different domains and/or ground domains, and/or domains adapted to carry operational signals.

It is thus defined at least one conductive domain on the guide 40 and this results in an increased performance of the probe head. For instance, the contact probes 10, which are short-circuited with respect to each other by the conductive portion 21, may be contact probes intended to carry ground signals, as well as they may be contact probes intended to carry supplies.

Furthermore, as above mentioned, the short-circuited probes may also be contact probes intended to carry input/output operating signals between the device under test and the testing apparatus interfaced with the probe head 20, as it occurs for instance in the loop-back technique.

Obviously, the probe head 20 may comprise any number of conductive portions 21 arranged in any way. For instance, the conductive portion may be arranged on an upper face F1 of the guide 40 (as illustrated in the non-limiting example of FIG. 1), as well as on a lower face F2 thereof, or in any other suitable way.

Moreover, it is possible to provide for the presence of a plurality of metallizations, electrically isolated from each other, configured to form a plurality of respective conductive planes for groups of contact probes. For instance it is possible to provide for a first conductive portion which short circuits ground probes and a second conductive portion which short circuits supply probes, or different metallizations for different supplies. I

It is also possible to provide for many other configurations, as described for instance in international patent application no. PCT/EP2017/082180 to the same Applicant. Even the method for making said conductive portion is not limited to one in particular, for instance it may be formed by depositing conductive material onto the ceramic guide.

In other words, the present invention is not limited by the number and arrangement of the conductive portions, which may be established based on the needs and/or circumstances.

As above indicated, the guide 40 is preferably a lower guide, since it is advantageous to short circuit the closest probes to the device under test; said guide could also be an intermediate guide, or the metallization could be formed both on the lower guide and on the intermediate guide. In this regard, it is noted that the present invention is herein illustrated based on a non-limiting example in which the guide 40 is a lower guide equipped with a conductive plate (as illustrated in FIGS. 1 and 2), although different configurations can be provided and the inventive concepts herein described also apply to possible other guides of the probe head 20 (such as for instance to the intermediate guide 40′).

It is noted that, in a probe head of the above type, in particular in case of numerous contact probes 10, the presence of the air-conveying system 60 alone may not be enough to ensure an effective heat dissipation, since the innermost probes (namely those surrounded by many other contact probes which are the outermost ones with respect thereto) are not affected by the air flow F, which mainly hits only the innermost probes.

Advantageously according to the present invention, there is also provided a heat dissipation conductive portion (indicated with reference number 65) formed on the guide 40 and arranged so that the air flow F of the air-conveying system 60 passes at the same. This heat dissipation conductive portion 65 may thus be hit by the air flow F, or in any case it may be arranged on the guide 40 in order to feel the beneficial effects of said air flow F. In particular, the heat dissipation conductive portion 65 is electrically connected to the conductive portion 21 so as to extend the conductive domain also in a further area of the guide 40 (where there is not the conductive portion 21) and so that the air flow F of the air-conveying system 60 facilitates the dissipation of the heat collected by said heat dissipation conductive portion 65, thus ensuring an optimal dissipation and a high performance of the probe head 20 as a whole. The connection between the portions 21 and 65 may occur by means of suitable tracks, which are shaped so as to pass between the remaining probes and the remaining domains.

In other words, the heat dissipation conductive portion 65 is a thermal pad (or exchange surface) which collects the generated heat and which is hit by the air flow F.

In this way, the heat generated by the contact probes 10 is first transferred to the conductive portion 21 and then it is advantageously transferred to the heat dissipation conductive portion 65, at which the air flow F acts, so that, thanks to this configuration, the air-conveying system 60 is able to facilitate the heat dissipation inside the probe head 20.

As for the conductive portion 21, also the heat dissipation conductive portion 65 may be arranged on a face of the guide 40, for instance the upper face FA as indicated in the non-limiting examples of the figures.

The heat dissipation conductive portion 65 may be made of a suitable conductive material (for instance the same material of the portion 21), however without being limited by the used material, or by the surface extension thereof.

As previously mentioned, a plurality of conductive portions corresponding to different conductive domains may be provided, each of said conductive domains being configured to short circuit probes adapted to carry a different respective signal, wherein at least one of said domains (for instance one of the innermost domains and thus a domain which is not directly interested by the air flow F) is connected to a respective heat dissipation conductive portion 65, which instead is in an outermost area on the guide.

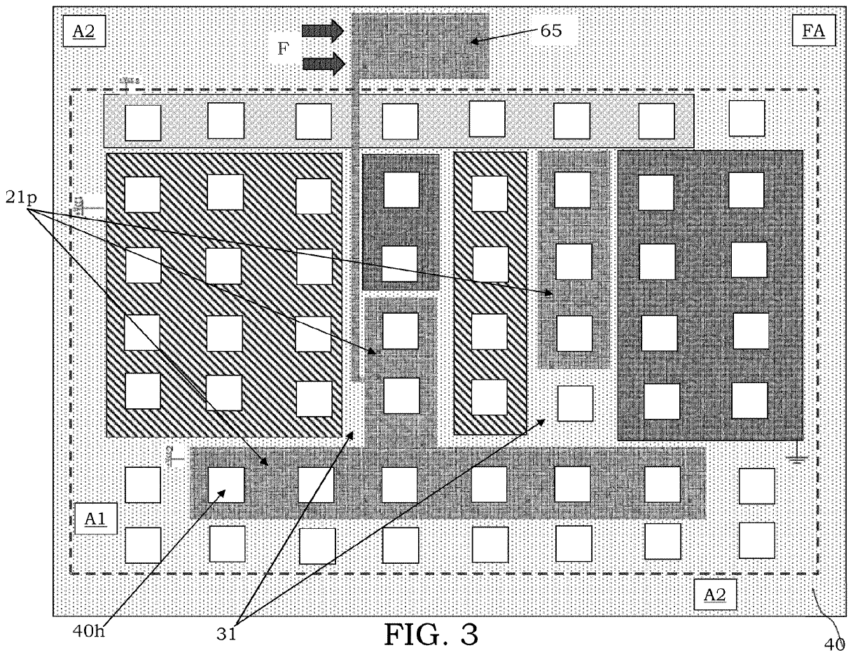

With particular reference to the diagram of FIG. 3, according to embodiments of the present invention, the contact probes 10 are generally included in at least one first area or active area (indicated with reference A1) of the guide 40, in said active aera the metallizations being thus also formed; it is then possible to also define a second area of the guide (indicated with reference A2) which does not include the contact probes 10. Obviously, the above areas are not limited by a particular shape; for instance, the second area A2 may be an area surrounding the active area A1, as well as more than one active area may be present on the guide.

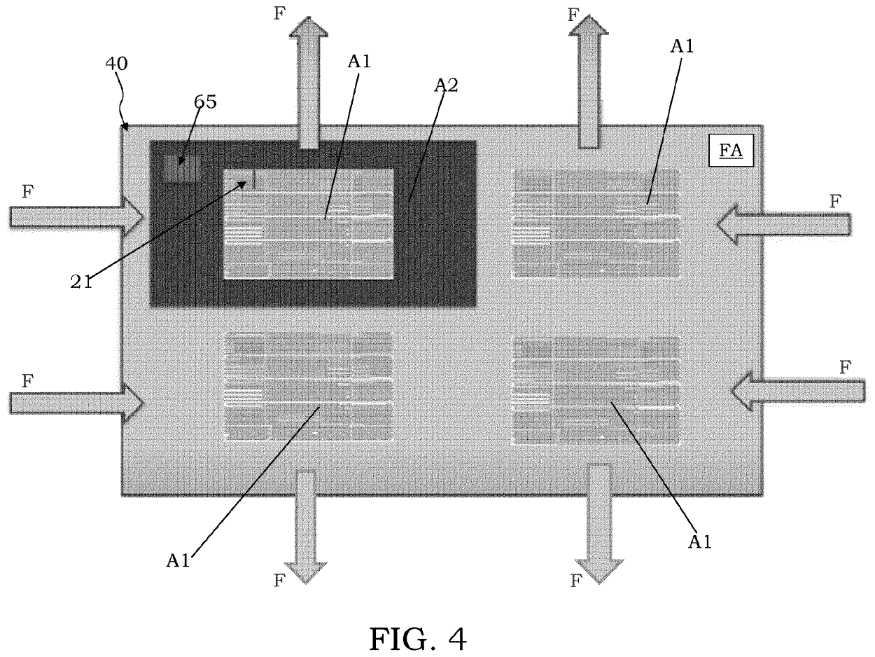

The active area A1 is thus contiguous to the second area A2, and (as also schematically represented in FIG. 4) the heat dissipation conductive portion 65 is formed in said second area A2, thereby extending the conductive domain outside the active area A1. Suitably, the air-conveying system 60 is configured to convey the air flow F at at least one portion of the second area A2, so as to facilitate the dissipation of the heat exchanged by the heat dissipation conductive portion 65 present in said second area A2, as above illustrated.

It is noted that, in connection with FIG. 4, although a rectangular outline has been created around the active area A1 to highlight the second area A2, said second area A2 is not obviously limited to the highlighted rectangle and may extend beyond (and therefore also the arrangement of the portion 65 is not limited to said rectangle). As above mentioned, there may also be multiple active areas A1 on a guide 40, for instance when the test of multiple dices in parallel (multi-dice devices) is performed, wherein the layout on the guide follows the layout of the devices to be tested.

Still with reference to FIG. 3, the conductive domains may be divided into distinct conductive sub-domains 21p separated from each other, wherein each of these conductive sub-domains 21p is configured to distribute a same determined type of signal between the contact elements 10 short circuited by them separately from the other conductive sub-domains. Such a configuration allows a greater flexibility in the design of the probe head, in particular when test of devices corresponding to many domains, in particular power domains, must be performed. As illustrated, the sub-domains 21p are separated by non-conductive areas 31 of the guide 40.

According to embodiments of the present invention, at least one of said conductive sub-domains 21p is connected to a respective heat dissipation conductive portion 65. In the schematic example of FIG. 3 four conductive domains (three power domains and one supply domain) are represented, and among these domains three are divided into respective sub-domains; one of these sub-domains is then connected with the heat dissipation conductive portion 65 arranged in the second area A2, thus facilitating the dissipation of the heat generated by the respective probes.

Obviously, it is not necessary for a domain to be divided into sub-domains, what matters is that at least one of the domains of the guide 40 (for instance an inner domain, as it occurs in the example of FIG. 4) is connected with the heat dissipation conductive portion 65. In particular, as already mentioned, according to embodiments of the present invention, one or more of the conductive domains which do not directly face toward the second area A2 are electrically connected with a respective heat dissipation conductive portion 65 extending in said second area A2, so as to facilitate the dissipation of the generated heat.

Furthermore, still with reference to FIG. 1, in an embodiment, the probe head 20 comprises one heat dissipation layer (indicated with reference 70), which is in contact with at least part of a face of the guide (the lower face FB in the example of FIG. 1, but not limited thereto), in order to obtain an even more effective dissipation.

In particular, this heat dissipation layer 70 may be made of a material selected from diamond, silicon carbide and silver-diamond compound with a diamond percentage between 50 and 99%, preferably diamond. The heat dissipation layer 70 is thus made of a high thermal conductivity material λ, for instance greater than 500 W/(m·K). Said high thermal conductivity λ in particular allows obtaining an optimal collection and subsequent dispersion of the heat produced by the probe head 20 during the testing operations.

The heat dissipation layer 70 may extend out of the active area A1, on the entire face of the guide 40 or even just on portions thereof; in some embodiments, it may also comprise lateral portions to wind (entirely or partially) said guide 40. In any case, it extends so as to facilitate the heat exchange with the air, and thus also with the air flow F conveyed by the system 60. In this way, the combination of the air flow F with the layer 70 ensures an even more effective dissipation thanks to the high conductivity of this layer 70.

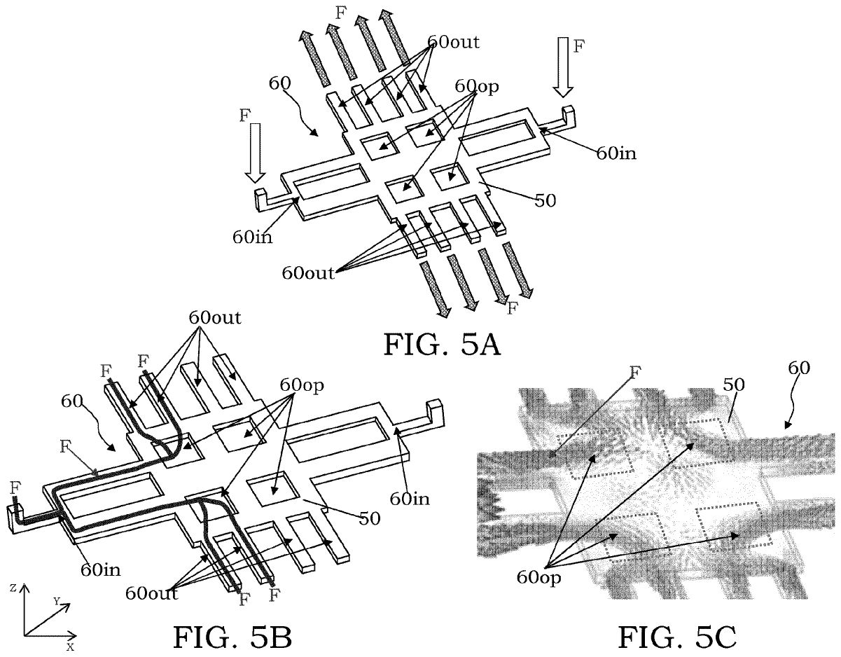

Finally, in an embodiment illustrated in FIGS. 5A-5C, the housing 50 is shaped so that the air-conveying system 60 is formed precisely in said housing 50, namely the air-conveying system 60 is part of the housing 50 itself (which thus may be seen as the body of said system 60, shaped to allow suitably conveying the air into the probe head 20.

As above mentioned, the air is generated by an external air source (not illustrated) which is associable with the probe head 20, and which then conveys said air thereinto by the conveying system 60, in particular by suitably formed ducts thereof (and thus by the channels of the housing).

In particular, the housing 50 is suitably shaped to allow conveying the air flow F coming from the external source thereinto by means of input ducts 60in and to cause said air flow F to flow out of the probe head 20 by means of output ducts 60out.

As illustrated in FIGS. 5A-5C, the input duct 60in is configured so that the air coming from the external source, in particular coming from the side where there is the testing apparatus and thus opposite the semiconductor wafer 23, be guided toward the guide 40 and possibly split by means of a bifurcation of said input duct 60in. The number of input ducts 60in (as well as the number of bifurcations of each of said ducts) may vary based on the number of dices (or chips) to be tested through the probe head 20 (for instance, four dices tested in parallel as illustrated in the figures).

Openings 60op are then provided in the housing for the passage of the contact probes 10 intended to test the corresponding die.

Both the vertical portion and the horizontal portion represented in FIGS. 5A and 5B may be seen as distinct portions of the same input duct 60in, which is suitably connectable (for instance at an opening in the vertical portion thereof) with means of the external source coming from the tester side, such as for instance tubes or similar means of the external source.

The single input ducts 60in, in particular the horizontal portions parallel to the guide, are configured to ensure an air flow F incident in a direction lying in a substantially plane which is parallel (for instance tangential) to the guide 40 and thus to the metallizations. As above indicated, the number of said channels, and thus of the areas hit by the tangential air flow, may vary based on the number of dices to be tested.

Therefore, this solution allows suitably conveying the forced air and is advantageous even for devices provided with multiple dices tested in parallel (as in the example of FIG. 4).

Furthermore, the output ducts 60out ensure that, for each single dice, there are at least two output paths for the air, also called output ducts since they extend parallel to the guide 40. In other words, for each dice, there are at least two output ducts 60out configured to ensure the above air flow parallel to the guide. In the embodiment of the figures, the output ducts are substantially orthogonal to the input ducts with respect to the plane where the guide lies.

The above configuration ensures a uniform air flow and on an extended area, as in the simulation of FIG. 5C and thus an optimal dissipation.

However, it is noted that the present invention is not limited to the particular shape and operation of the air-conveying system 60, which possibly may also have another structure, as well as it may comprise conventional means such as tubes, etc., which in order not to burden the present description, have not been described; what matters is that the air flow F passes at the heat dissipation conductive portion 65.

In conclusion, the present invention thus allows brilliantly overcoming the technical problem, providing the above probe head, and solving all of the drawbacks of the prior art.

Advantageously according to the present invention, a heat dissipation structure able to collect and dissipate the heat generated during the testing operations of the probe head is made; this structure collects the heat that is generated, for instance due to the friction of the contact probes sliding in the guide holes or due to the signals that pass through said contact probes and that may increase the temperature thereof (for instance power signals), and facilitates the dispersion thereof into the environment, in particular by air dissipation through a forced flow air.

The air-conveying system, in combination with the heat dissipation conductive portion formed outside the active areas of the guide, suitably limits the increase in the operation temperature of the probe head, avoiding malfunctions in a simple way.

The above air-conveying system is adapted, through its ducts, to convey air into the probe head, in particular toward the heat dissipation conductive portion (and possibly toward the high conductivity coating layer used in combination with the described solution), so as to improve the dissipation of the heat produced by the probe head and collected by said heat dissipation conductive portion, already inside the probe head itself. Indeed, the forced air flow is sent to the heat dissipation conductive portion, thus also allowing dispersing the heat of the innermost probes (in particular the inner power probes) which, in the absence of said portion, would be less affected by said air flow.

Obviously, a person skilled in the art, in order to meet contingent and specific requirements, may make to the above-described probe head numerous modifications and variants, all included in the scope of protection of the invention as defined by the following claims.

1. A probe head for testing a device under test, comprising:
a plurality of contact probes comprising a body extending along a longitudinal axis between a first end portion and a second end portion, said end portions being adapted to contact respective pads;
a guide provided with guide holes for housing the contact probes; and
an air-conveying system configured to convey an air flow into the probe head and to thereby facilitate heat dissipation,
wherein the probe head comprises a conductive portion formed on the guide, said conductive portion including a group of holes of the guide holes and adapted to contact and short circuit a corresponding group of contact probes housed in said group of holes, said contact probes being intended to carry a determined type of signal, thereby defining a conductive domain on the guide, and
wherein the probe head further comprises a heat dissipation conductive portion formed on the guide and arranged so that the air flow of the air conveying system passes at the same, said heat dissipation conductive portion being connected to the conductive portion to extend the conductive domain and so that said air flow of the air conveying system facilitates the dissipation of the heat exchanged by said heat dissipation conductive portion.

2. The probe head according to claim 1, comprising a plurality of conductive portions corresponding to different conductive domains, each of said conductive domains being configured to short circuit probes adapted to carry a different respective signal, and wherein at least one of said domains is connected to a respective heat dissipation conductive portion.

3. The probe head according to claim 2, wherein the conductive domains are different power domains, and/or ground domains, and/or domains adapted to carry operational signals.

4. The probe head according to claim 1, wherein at least one conductive domain is divided into distinct conductive sub-domains separated from each other, and wherein each of said conductive sub-domains is configured to distribute a same determined type of signal between the contact elements short circuited by them separately from the other conductive sub-domains, wherein at least one of said conductive sub-domains is connected with a respective heat dissipation conductive portion.

5. The probe head according to claim 1, wherein:
the guide is a lower guide, and/or
the guide is an intermediate guide of the probe head, wherein a lower guide is arranged between said intermediate guide and the device under test.

6. The probe head according to claim 5, further comprising an upper guide separated from the lower guide and provided with respective guide holes, the lower guide being the guide closest to the device under test.

7. The probe head according to claim 1, wherein the contact probes are included in a first area or active area of the guide, said active area being contiguous to a second area of said guide, wherein the second area does not include the contact probes, the air conveying system being configured to convey the air flow at a part of the second area, and wherein the heat dissipation conductive portion is formed in said second area, thereby extending the conductive domain out of the active area.

8. The probe head according to claim 1, wherein the conductive portion and the heat dissipation conductive portion are arranged on one face of the guide.

9. The probe head according to claim 8, further comprising a heat dissipation layer which is in contact with a part of the face of the guide, wherein said heat dissipation layer is made of a high thermal conductivity material selected from diamond, silicon carbide and silver-diamond compound with a diamond content between 50 and 99%.

10. The probe head according to claim 1, comprising a housing configured to house the contact probes, wherein the air conveying system is configured to convey the air flow into said housing.

11. The probe head according to claim 10, wherein the housing is configured so that at least part of the air conveying system is formed in said housing, which is shaped to allow conveying the air flow thereinto by means of input ducts and to cause said air flow to flow-out by means of output ducts, wherein said ducts are configured so that the input air flow is in a direction lying in a plane parallel to the guide and the output air flow is divided into at least two flow portions, the input air flow being split based on the number of devices to be tested by said probe head.

12. The probe head according to claim 3, wherein the conductive domains are power domains.

13. The probe head according to claim 9, wherein the high thermal conductivity material is diamond.
